(19) United States
(12) Patent Application Publication
(10) Pub. No.: US 2014/0097003 A1
(43) Pub. Date: Apr. 10, 2014

(54) ELECTRICAL COMPONENTS AND METHODS AND SYSTEMS OF MANUFACTURING ELECTRICAL COMPONENTS

(71) Applicants: TYCO ELECTRONICS CORPORATION, BERWYN, PA (US); TYCO ELECTRONICS AMP GMBH, Bensheim (DE)

(72) Inventors: SOENKE SACHS, Frankfurt am Main (DE); HELGE SCHMIDT, SPEYER (DE); MICHAEL LEIDNER, LAMBRECHT (DE); EVA HENSCHEL, BENSHEIM (DE); DOMINIQUE FRECKMANN, SAN FRANCISCO, CA (US); MARJORIE MYERS, MOUNT WOLF, PA (US)

(73) Assignees: TYCO ELECTRONICS AMP GMBH, Bensheim (DE); TYCO ELECTRONICS CORPORATION, BERWYN, PA (US)

(21) Appl. No.: 13/838,008

(22) Filed: Mar. 15, 2013

Related U.S. Application Data
(60) Provisional application No. 61/710,395, filed on Oct. 5, 2012.

(51) Int. Cl. B23K 15/00; H05K 1/02

(52) U.S. Cl. CPC B23K 15/0006; H05K 1/0271
USPC 174/250; 219/121.35; 219/121.12

(57) ABSTRACT

A method of manufacturing an electrical component includes providing a substrate, applying an insulating layer on the substrate, applying a circuit layer on the insulating layer, irradiating the insulating layer with an electron beam to transform the insulating layer, and irradiating the circuit layer with an electron beam to transform the circuit layer. The substrate may be a metallic substrate that is highly thermally conductive. The insulating layer provides electrical isolation and effective heat transfer between the circuit layer and the substrate. The method may include coupling a light emitting diode module or other active circuits requiring thermal management to the circuit layer resident on the electrically insulating/thermally conducting layer.

### CROSS REFERENCE TO RELATED APPLICATIONS

This application claims the benefit of U.S. Provisional Application No. 61/710,395 filed Oct. 5, 2012 titled ELECTRICAL COMPONENTS AND METHODS AND SYSTEMS OF MANUFACTURING ELECTRICAL COMPONENTS, the subject matter of which is herein incorporated by reference in its entirety.

### BACKGROUND OF THE INVENTION

The subject matter herein relates generally to electrical components and methods and systems of manufacturing electrical components.

Active electronic high performance elements such as high performance light emitting diodes (LEDs) generate large amounts of heat, which must be dissipated adequately for proper operation. In the case of LEDs, the heat dissipation occurs on the rear side of the component, as the generated light is radiated from the front side.

Conventional systems provide heat dissipation using a heat sink (e.g. aluminum) with an organic insulating layer deposited thereon. The circuit for driving the active electronic components is applied to the organic insulating layer. The organic insulating layer (e.g. epoxy with added particles to increase the thermal conductivity) has to transfer the heat to the heat sink. Conventional insulating layers have problems. For example, the insulating layer needs to feature an adequate breakdown voltage to sufficiently insulate the heat sink from the voltage carrying circuit (in some cases up to high voltages of 1000 V magnitude). Compared to conventional insulators, organic insulating layers typically exhibit smaller breakdown voltages. Relatively thick layers of the organic insulating layers are needed to achieve the breakdown voltages, leading to lower thermal conductivity and therefore poorer thermal coupling to the heat sink.

The circuits are conductive metallic structures applied to the insulating layers. Application of such layers are typically accomplished either by deposition of the conductive metallic structures by using masks (e.g., vacuum evaporation, sputtering, chemical vapor deposition, plating) or by printing metallic pastes or inks on the substrate and then a subsequent thermal post-treatment. Problems exist for these conventional application processes. For example, the smallest producible feature sizes of the conductive metallic structures in deposition from a gas phase are limited by the structure sizes of the masks used (usually on the order of millimeters or greater), and a large part of the material used will not be utilized for the actual coating and must therefore be expensively recycled. Additionally, printed and conventional thermally treated structures (e.g. in the oven) feature poorer electrical properties in comparison to pure metals, since the printing requires the addition of non-metallic additives such as glue, binder or additives to adjust the flow properties necessary for printing. In the thermal post-treatment these additives are only partially removed from the layer, causing the coating layer to have poorer electrical properties than coating layers having higher metallic contents, such as those approaching pure metal. Additionally, thermal stress during the deposition or during the thermal treatment is problematic. Some methods, such as MID (molded interconnect device) and LDS (laser direct structuring), use special polymers which contain metal catalysts. Use of specialty materials in such processes is expensive and the chemical coating process can take a very long time.

A need remains for methods and systems of manufacturing electrical components that are cost effective and produce high quality electrical components with efficient thermal transfer from the electrical modules to the heat sink.

### BRIEF DESCRIPTION OF THE INVENTION

In one embodiment, a method of manufacturing an electrical component is provided that includes providing a substrate, applying an insulating layer on the substrate, applying a circuit layer on the insulating layer, irradiating the insulating layer with an electron beam to transform the insulating layer, and irradiating the circuit layer with an electron beam to transform the circuit layer. The substrate may be a metallic substrate that is highly thermally conductive. The insulating layer provides electrical isolation between the circuit layer and the substrate. The method may include coupling a light emitting diode module to the circuit layer.

Optionally, the irradiating of the insulating layer and the circuit layer may occur simultaneously, or irradiating of the insulating layer may occur prior to applying the circuit layer on the insulating layer. The irradiating of the circuit layer may include heating the circuit layer to melt the circuit layer to form an electrical conductor. Optionally, the circuit layer and or the insulating layer may be preheated, such as to a temperature below a melting point thereof prior to irradiating. The irradiating may then heat the layer(s) to a temperature above the melting point thereof.

Optionally, the circuit layer may have a low binder concentration and a high metal concentration. The irradiating process may vaporize substantially all the binder leaving a substantially pure metallic circuit layer. The insulating layer may have glass or ceramic forming materials. Irradiating the insulating layer may transform the glass or ceramic forming materials into a glass or ceramic insulating layer. The insulating layer may be applied by printing the insulating layer directly on the outer surface of the substrate. The circuit layer may be applied by printing the circuit layer directly on the insulating layer. The circuit layer may be electrically grounded during the irradiating process.

In another embodiment, an electrical component is provided having a substrate having an outer surface, an insulating layer selectively applied to the outer surface and a circuit layer selectively applied to the insulating layer. The insulating layer is configured in a pre-processing state and in a post-processing state after irradiating with an electron beam. The insulating layer is transformed from the pre-processing state to the post-processing state. An electron beam at least partially penetrates the insulating layer during the irradiating to transform the insulating layer. The circuit layer is configured in a pre-processing state and in a post-processing state after irradiating with an electron beam. The circuit layer is transformed from the pre-processing state to the post-processing state. An electron beam at least partially penetrates the circuit layer during the irradiating to transform the circuit layer.

In a further embodiment, an electrical component forming system is provided including a chamber, an irradiation source generating electron beams, and a substrate positioned in the chamber. The substrate has an insulating layer selectively applied to the substrate and corresponding electron beams at least partially penetrating the insulating layer to transform the insulating layer. The substrate has a circuit layer selectively applied to the insulating layer and corresponding electron beams at least partially penetrating the circuit layer to transform the circuit layer.

### BRIEF DESCRIPTION OF THE DRAWINGS

FIG. 1 illustrates an electrical component being manufactured to include an electronic module on a substrate.

FIG. 2 illustrates an electrical component forming system used to irradiate an electron beam at the electrical component in accordance with an exemplary embodiment.

FIG. 3 illustrates the interaction of the electron beam with the coating layers of the electrical component.

FIG. 4 illustrates a process for forming an electrical component.

FIG. 5 illustrates a process for forming an electrical component.

FIG. 6 illustrates a method of manufacturing an electrical component.

### DETAILED DESCRIPTION OF THE INVENTION

Embodiments described herein include a method of manufacturing an electrical component that includes irradiating an insulating layer and a circuit layer with an electron beam to transform the layers. Embodiments described herein include a system that uses an electron beam to irradiate an insulating layer and a circuit layer on the insulating layer to transform the layers to enhance one or more properties of the layers. Embodiments described herein include an electrical component having an insulating layer and a circuit layer that are transformed by energy from an electron beam to enhance properties of the layers. The insulating layer is deposited on a substrate and the circuit layer is deposited on the insulating layer.

Embodiments described herein may include an electrical component having the form of a metal clad circuit board with electrical conductors forming circuits thereon, the electrical conductors being processed by an electron beam. An insulating layer is provided between the circuits and the metal substrate of the metal clad circuit board. The insulating layer and the electrical conductors are both irradiated with an electron beam to transform the layers.

Embodiments described herein may form a highly thermally conductive but electrically insulative insulating layer by using an electron beam processing technique. For example, heat may be generated inside the insulating layer quickly (e.g. within microseconds), which may transform the insulating layer, such as to solidify the insulating layer. The heat may be used to melt or remelt some or all of the compounds or materials of the insulating layer. In other embodiments, the electrons of the electron beam may react with materials of the insulating layer to transform the insulating layer. Some of the material of the insulating layer may be segregated and/or evaporated by the electron beam during processing to transform the composition of the insulating layer. The material used for the insulating layer may be selected to function well with the electron beam processing. For example, glass or ceramic forming materials may be used as the structure of the insulating layer. A dense, highly thermally conductive nano-scale material may be achieved by processing the insulating layer with the electron beam.

Embodiments described herein may achieve a high quality electrical conductor by using an electron beam processing technique. For example, heat may be generated inside the circuit layer quickly (e.g. within microseconds), which may transform the circuit layer to enhance electrical properties of the circuit layer. The heat may be used to melt or remelt some or all of the compounds or materials of the circuit layer. In other embodiments, the electrons of the electron beam may react with materials of the circuit layer to transform the circuit layer. Some of the material of the circuit layer may be segregated and/or evaporated by the electron beam during processing to transform the composition of the circuit layer. The material used for the circuit layer may be selected to function well with the electron beam processing. For example, non-alloying metal combinations may be used as the metallic structure of the circuit layer. A hard, highly conductive nano-scale material may be achieved by processing the circuit layer with the electron beam.

Embodiments described herein may provide a circuit layer and electrical conductor with substantially all residual non-metallic (e.g. organic) material from the paste or ink (used to apply the circuit layer to the insulating layer) removed during electron beam processing of the circuit layer. The post-processed electrical conductor may be a dense, pore-free metallic coating. The circuit layer may have an initial concentration of non-metallic material (e.g. binder) that is lower, even much lower, than conventional paste (e.g. paste that is processed in a thermal oven). The circuit layer may have a final concentration of non-metallic material (e.g. binder) that is lower, even much lower, than components made with conventional paste (e.g. processing in a thermal oven).

Embodiments described herein may enhance or select control parameters to achieve a high quality electrical conductor. The interaction of the electron beam with the applied coating layers and substrate may be considered. For example, the interaction of parameters including the ink or paste composition, the printing technique (e.g. micro dispensing, screen printing, pad printing, ink jet printing, aerosol jet printing, and the like), and/or the electron beam levels may be considered and balanced.

Embodiments described herein produce an electrical conductor that may have properties necessary to provide stable electro-mechanical performance throughout the lifetime of the electrical component. For example, the electrical conductor may have a low and stable electrical contact resistance, good soldering characteristics, a good wear performance, and/or good resistance to environmental degradation factors such as corrosive gas or high temperature exposures. The electron beam may be precisely controlled allowing for high spatial resolution of the electrical conductor. The finish of the electrical conductor may be controlled by the electron beam process and the materials of the circuit layer to achieve the desired properties. For example, the electrical conductor may have appropriate coating qualities such as layer composition, film thicknesses, roughness, topography, structure, and the like.

Embodiments described herein produce an electrical conductor that may have properties necessary to provide good thermal characteristics for heat dissipation from the circuit layer to the metal substrate. The insulating layer may provide good insulating characteristics to provide an adequate breakdown voltage to sufficiently insulate the metal substrate from the voltage carrying circuit layer.

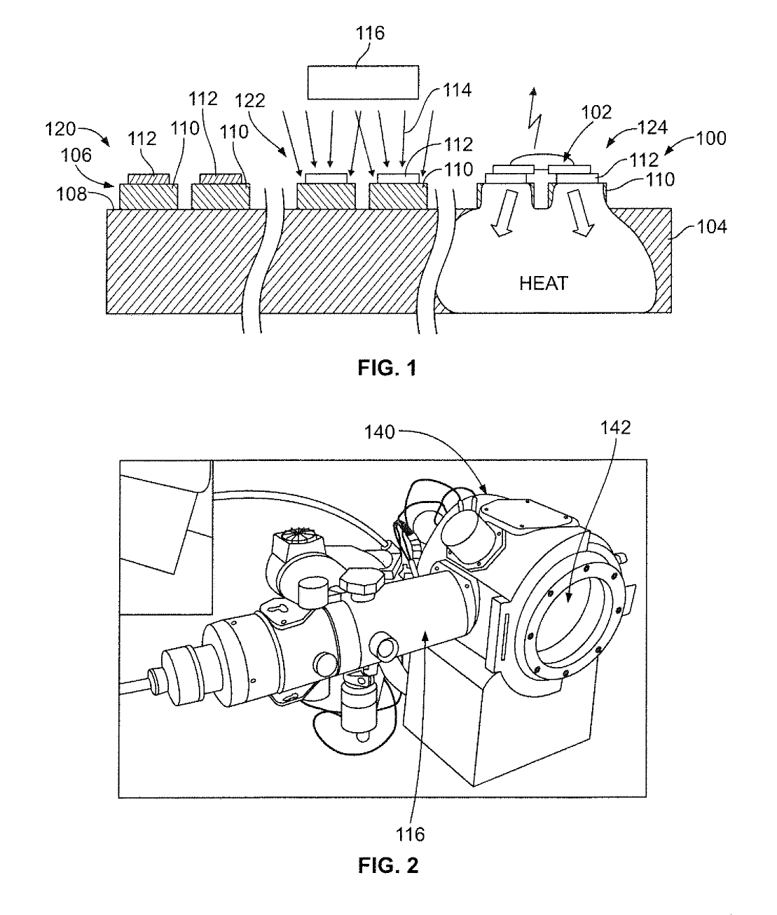

FIG. 1 illustrates an electrical component 100 being manufactured to include an electronic module 102 on a substrate 104. In an exemplary embodiment, the electronic module 102 is a light emitting diode (LED) module, and may be referred to hereinafter as an LED module 102, however other types of electronic modules 102 or other active circuits requiring thermal management may be mounted to the substrate 104. In an exemplary embodiment, the electronic module 102 is a high power device, such as a high power LED. The high power tends to generate excessive heat, which needs to be dissipated to protect the electrical component 100. In an exemplary embodiment, the substrate 104 is a metal substrate or heat sink that dissipates heat from the LED module 102. The electrical component 100 may be referred to as a metal clad circuit board, however other types of electrical components 100 may be manufactured using the methods and systems described herein.

During processing, coating layers 106 are applied to an outer surface 108 of the substrate 104. Any number of coating layers 106 may be applied to the substrate 104. In the illustrated embodiment, the coating layers 106 include an insulating layer 110 applied to the substrate 104 and a circuit layer 112 applied to the insulating layer 110. The LED module 102 is mounted to the circuit layer 112. For example, the LED module 102 may be soldered to the circuit layer 112. The insulating layer 110 provides electrical isolation between the circuit layer 112 and the substrate 104. In an exemplary embodiment, the insulating layer 110 may be highly thermally conductive to efficiently dissipate heat from the circuit layer 112 and corresponding LED module 102 mounted to the circuit layer 112.

In an exemplary embodiment, the coating layers 106 are processed by electron beams 114 generated from an irradiation source 116. Optionally, both coating layers 106 may be irradiated by the electron beams 114 simultaneously. For example, the insulating layer 110 may be applied to the substrate 104, then the circuit layer 112 may be applied to the insulating layer 110 and then both layers 110, 112 are irradiated. Alternatively, the insulating layer 110 may be applied to the substrate 104 and then irradiated with the electron beams 114. The circuit layer 112 is then applied to the processed insulating layer 110 and subsequently irradiated with electron beams 114. Optionally, the electron beam may be utilized in a non-adiabatic electron beam processing technique.

FIG. 1 illustrates the electrical component 100 at different stages or states of the processing. For example, at 120, the coating layers 106 of the electrical component 100 are shown at pre-processing states. At 122, the coating layers 106 of the electrical component 100 are shown at a processing state, at which the electron beams 114 are directed toward the coating layers 106. The electron beams 114 at least partially penetrate the coating layers 106. For example, some electron beams 114 may be directed to penetrate the insulating layer 110 while other electron beams 114 may be directed to penetrate the circuit layer 112. Optionally, the electron beams 114 directed to the insulating layer 110 may have different characteristics than the electron beams directed to the circuit layer 112. The coating layers 106 are irradiated to transform one or more properties of the material of such coating layers 106. At 124, the coating layers 106 of the electrical component 100 are shown at a post-processing state, after irradiation from the electron beam 114. The LED module 102 is shown coupled to the circuit layer 112 after the irradiation by the electron beams 114.

The substrate 104 is used to form a circuit board, such as a metal clad circuit board. The circuit layers 112 form conductive traces defining circuits of the circuit board. The substrate 104 is a metallic substrate, such as an aluminum heat sink.

The insulating layer 110 is a thermally highly conductive layer. Optionally, the insulating layer 110 may be a hard anodized layer. The insulating layer 110 may be applied by printing an ink or paste on the outer surface 108. Optionally, the insulating layer 110 may be applied directly to the outer surface 108. Alternatively, one or more layers may be provided between the substrate 104 and the insulating layer 110. The substrate 104 may be cleaned and de-oxidized prior to printing the insulating layer 110 on the outer surface 108.

In an exemplary embodiment, the insulating layer 110 includes metal oxides, such as oxides of aluminum, silicon, titanium, magnesium, and the like. The insulating layer 110 may include other particles, such as enamel, glass, ceramic, porcelain, and the like. The insulating layer 110 may include borates, silicates, fluorides, alkali metals, lead, aluminum, and the like. The insulating layer may include organic material, such as epoxy, resin, binder, and the like, which may include metallic particles or flakes to increase the thermal conduction of the insulating layer 110. For example, the organic carriers may be highly filled with thermally highly conductive particles, such as metal oxides, aluminum oxide, silicon oxide, aluminum nitride, diamond, and the like. Particles of various shapes and sizes may be used. The insulating layer 110 may include a binder to promote as-printed adhesion, and/or a surfactant to prevent particle agglomeration. The insulating layer 110 may include a solvent needed and/or other additives to adjust the viscosity of the ink/paste required for the printing process(es). The insulating layer 110 material may include metal precursors or other substances which can be chemically reduced during irradiation with the electron beams 114.

In an exemplary embodiment, the insulating layer 110 may be a microstructure of micro particles and/or nano-particles. The particles of the insulating layer 110 are melted with the electron beam 114 to generate a solution where the materials are mixed on the atomic scale. Optionally, the insulating layer 110 may be rapidly cooled to quickly solidify the solution to inhibit phase separations, grain growth and/or excessive heat conduction into the metal heat sink 104. The metal heat sink defining the substrate 104 aids in quickly dissipating the heat from the insulating layer 110 during and after irradiation. Having a good mixture of the materials and having quick solidification, leads to a fine material microstructure.

The insulating layer 110 may be applied by one of various different printing techniques, such as screen printing, pad printing, ink jet printing, aerosol jet printing, micro dispensing, spin coating, a wiping application and the like. Other application techniques other than printing may be used in alternative embodiments to apply the insulating layer 110 to the substrate 104. For example, the insulating layer 110 may be applied by powder coating, spraying, dip immersion or other processes. The application technique may selectively apply the insulating layer 110 to the substrate 104, such as along a predetermined circuit trace path. The printing technique may allow for a standardized pattern to be printed on the substrate 104, and the printing may be done discontinuously, such as in a batch printing application or continuously, such as in a reel-to-reel printing application. The printing technique may be chosen according to the smallest structure sizes of the paste or ink, the layer thicknesses being applied, the composition of the insulating layer material, and the like.

The circuit layer 112 may be applied by printing a conductive or metallic ink or paste on the insulating layer 110. The insulating layer 110 is between the circuit layer 112 and the substrate 104 to provide electrical isolation therebetween. Optionally, the circuit layer 112 may be applied directly to the insulating layer 110. Alternatively, one or more layers may be provided between the insulating layer 110 and the circuit layer 112.

In an exemplary embodiment, the circuit layer 112 includes metal particles of various shapes and sizes. The circuit layer 112 may include a binder to promote as-printed adhesion and/or a surfactant to prevent metal particle agglomeration (e.g. 1-2 wt %). The circuit layer 112 may include a solvent and/or other additives needed for the printing process(es). Optionally, the circuit layer 112 may contain additional flux additives (e.g. commercial brazing flux, borax, and potassium-tetraborate), such as at levels between 1 and 10 wt %. The flux may be added to adjust a wetting behavior of the circuit layer 112 during post processing with the electron beam 114. In an exemplary embodiment, the circuit layer 112 may have a high metal concentration (e.g. greater than 50 wt %). In an exemplary embodiment, the metal particles may be 100% silver particles. In another embodiment, the metal particles may be 100% copper particles or another highly conductive metal. Other types of metals may be used in alternative embodiments, such as gold, aluminum, nickel, silver, molybdenum, tin, zinc, titanium, palladium, platinum, and the like and/or alloys thereof. The circuit layer 112 material may include metal precursors which can be chemically reduced to metals. For example, metal salts, metal oxides, and other metal compounds may be used, such as silver chloride, tin chloride, silver nitrate. The precursors may include metals having low melting points, such as tin, zinc, copper, silver, and the like. When using a mixture of metals or alloys, intermetallic structures may be created during the electron beam processing to achieve desired characteristics or properties for the coating layers 106.

In an exemplary embodiment, the circuit layer 112 may be a microstructure of micro particles and/or nano-particles. Optionally, the circuit layer 112 may include a mixed powder of solid metal particles, such as Ag particles, with a binder, solvent and/or flux mixture. The metal particles are melted with the electron beam 114 to generate a solution where the materials are mixed on the atomic scale. Optionally, the circuit layer 112 may be rapidly cooled to quickly solidify the solution to inhibit phase separations and grain growth. For example, the metal heat sink defining the substrate 104 may be used to dissipate heat from the circuit layer 112, with the heat also passing through the highly thermally conductive insulating layer 110. Having good mixture of the materials and having quick solidification, leads to a fine material microstructure. Optionally, differently sized and shaped metal particle may be used. Precursors, which are reduced to metallic particles during the irradiation and melting process (e.g. metal salts, metal oxides) may be used. Optionally, a diffusion barrier layer may be provided between the insulating layer 110 and the circuit layer 112, such as to reduce interdiffusion between the material of the insulating layer 110 and the material of the circuit layer 112.

The binder concentration may be relatively low (e.g. less than 5 wt %), such as compared to the metal particle concentration. The binder concentration may be relatively low compared to conventional pastes that are used in conventional thermal oven post-treatment applications. The binder concentration may be between approximately 25 wt % and 5 wt %. Alternatively, the binder concentration may be very low (e.g. less than 1 wt %). Examples of binders include dextrins, polyvinyl butyral resins (e.g. Butvar), hydroxypropylcellulose (e.g. Klucel®), but other types of binders may be used in alternative embodiments. The binder may include glue or other additives to change a viscosity of the coating material for ease of application to the insulating layer 110.

The circuit layer 112 may be applied by one of various different printing techniques, such as screen printing, pad printing, ink jet printing, aerosol jet printing, micro dispensing, spin coating, a wiping application and the like. Other application techniques other than printing may be used in alternative embodiments to apply the circuit layer 112 to the insulating layer 110. For example, the circuit layer 112 may be applied by powder coating, spraying, dip immersion or other processes. The application technique may selectively apply the circuit layer 112 to the insulating layer 110, such as along a predetermined circuit trace path. The printing technique may allow for a standardized pattern to be printed on the substrate 104, and the printing may be done discontinuously, such as in a batch printing application or continuously, such as in a reel-to-reel printing application. The printing technique may be chosen according to the smallest structure sizes of the paste or ink, the layer thicknesses being applied, the composition of the coating layer material, and the like.

With additional reference to FIG. 2, FIG. 2 illustrates an electrical component forming system 140 used to irradiate the electron beam 114 at the electrical component 100 in accordance with an exemplary embodiment. The system 140 may be an electron beam micro welder capable of producing the electron beam 114. The processing may be performed in a vacuum chamber 142. The power of the irradiation source 116 may be controlled during processing. The energy density of the electron beam 114 may be controlled during processing. The deflection speed of the electrons may be controlled during processing. The maximum acceleration voltage may be controlled during processing. The maximum electron beam current may be controlled during processing. The beam focus spot size and depth on the target may be controlled during processing. The system 140 may control the electron beams 114 to focus on more than one beam focus spot, such as to irradiate the insulating layer 110 and the circuit layer 112 simultaneously. The electron beam 114 may be controlled based on properties of the deposited coating layer 106 (e.g. layer thickness, layer composition) and the material properties of the coating layer 106 (e.g. density, thermal conductivity, chemical composition).

The system 140 may be equipped with both a backscatter electron and a secondary electron detector which can be used to produce electron beam images of the work piece, similar to a Scanning Electron Microscope (SEM). The images can be viewed live on a screen or saved using a computer. The system 140 may include software to control the functions of the irradiation source 116, such as to program the electron beam 114 to scan defined paths over the sample or to irradiate defined patterns. The software may allow synchronous movements of the electron beam 110 with the irradiated sample, such as a continuously moved reel. In such a way, a continuous remelting process is possible. Optionally, the system 140 may include a heat sink, such as a thick aluminum plate heat sink having a high thermal mass and positioned in good thermal contact with the target.

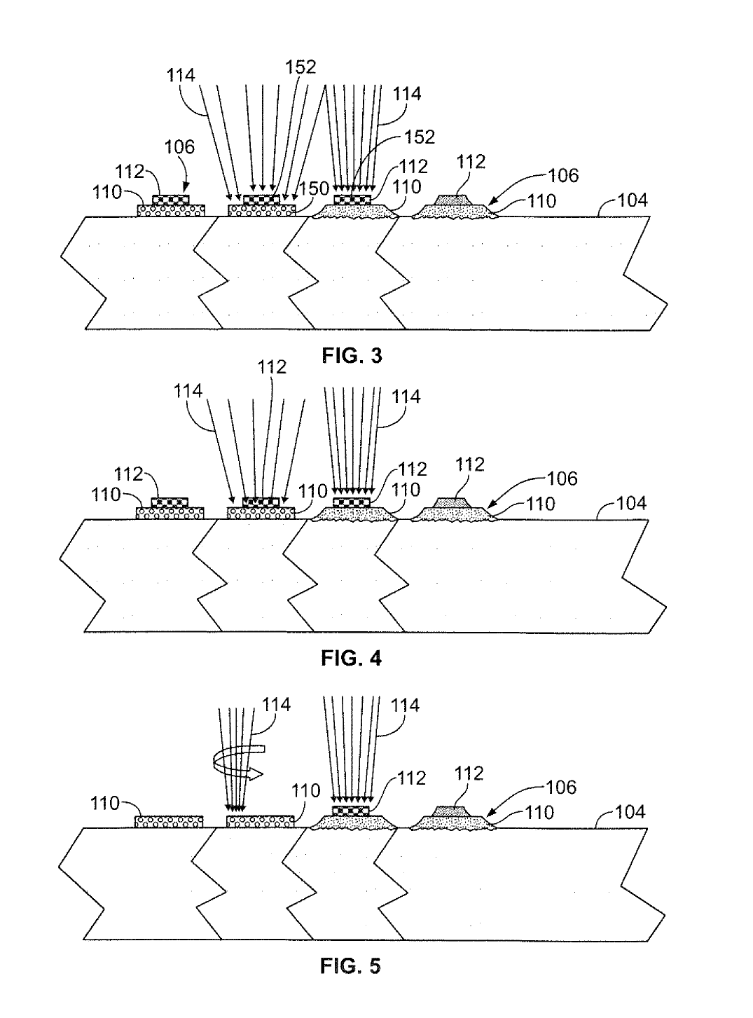

FIG. 3 illustrates the interaction of the electron beam 114 with the coating layers 106. In the illustrated embodiment, both the insulating layer 110 and the circuit layer 112 are printed prior to irradiating. During irradiation, some of the electron beams 114 are focused internal of the insulating layer 110 and some of the electron beams 114 are focused internal of the circuit layer 112. The electron beams 114 at least partially penetrates the respective coating layer 106. In an exemplary embodiment, a beam focus spot 150 is in the insulating layer 106 and a beam focus spot 152 is in the circuit layer 112. The electron beams 114 are not focused in the substrate 104, however the substrate dissipates heat from the coating layers 106. Irradiation or heating of the substrate 104 is limited by having the electron beam 114 focused on the coating layers 106. As the impinging electrons of the electron beams 114 are scattered by the material of the coating layers 106, kinetic energy of the electrons is converted into heat energy. The scattering probability may be dependent on the energy of the electrons, on the density of the irradiated material of the corresponding coating layer 106, on the beam focus depth, and the like. Optionally, the penetration depth of the electron beam may be between 0.5 μm and 20 μm. In an exemplary embodiment, a characteristic of the energy dependence of the scattering probability is that the maximum of the generated heat density does not lie at the surface of the material but at about ⅓ of the penetration depth. Heat is generated not only at the surface but inside the material of the coating layers 106. A part of the electrons are reflected or re-emitted from the coating layers 106. Such electrons can be utilized to generate in-situ SEM pictures during irradiation, such as to control the irradiation process via a feedback control system.

The power of the heat which is generated is dependent on the electron current for a fixed acceleration voltage. The product of the acceleration voltage and the beam current gives the power of the beam. The power can be adjusted by controlling the electron current and/or the acceleration voltage. Another parameter that may be adjusted to control the irradiation process is the duration of irradiation at or near a spot of the coating layer 106. The printed material of the coating layer 106 melts if the generated heat exceeds the thermal energy needed to heat the material to its melting point and the latent heat of fusion of the material. Having the heat energy focused in the coating layers 106, as opposed to the substrate 104, generates heat and melting of the coating layers 106 very quickly. The coating layer 106 and/or the substrate layer 104 may be heated to a temperature below the melting point to change characteristics of the layer(s) by reacting materials and/or sintering the layer(s). Optionally, the substrate 104 may act as a heat sink to quickly dissipate heat from the coating layers 106 after irradiation enabling high cooling rates of the molten film. Quick heating and cooling rates may affect the properties of the coating layer 106. For example, the hardness of the circuit layer 112 may be higher with quick heating and cooling as opposed to slow heating and cooling of the circuit layer 112, as is typical of thermal curing in a thermal oven where the substrate 104 is heated in addition to the paste. Additionally, more heat energy is needed to heat the paste in a thermal oven because the substrate is heated in addition to the paste.

Since the binders typically have a mass density an order of magnitude lower than the metal particles in the coating layers 106, the volume percentage of the binders in the coating layers 106 are even higher. For instance, a conventional paste typical for use in an application cured in a thermal oven is a 90Ag/10Mo material with 23 wt % Butvar binder, which is a high binder concentration and is borderline very high binder concentration. Such conventional paste has a binder volume fraction of approximately 75%. The high or very high binder concentrations of conventional pastes is needed to securely fix the printed structures onto the substrate and the binder remains post thermal treatment using conventional thermal ovens.

In an exemplary embodiment, for processing with the electron beam 114, the coating layers 106 do not require such a high binder content as the binder is only needed to keep the printed coating layers 106 in position on the substrate 104 long enough to transfer the substrate 104 to the electron beam 114 for irradiation. For example, a binder content may be approximately 1 wt %, greatly reducing the volume percentage as well. After melting, the coating layers 106 are dense and have good adhesion. In an exemplary embodiment, the binder is intended to be substantially entirely removed from the coating layers 106 during the irradiation process, such as by evaporation or by decomposition. Using a low concentration of binder in the coating layers 106 allows quicker and more thorough evaporation or removal of the binder during irradiation. Having less binder in the insulating layer 110 makes the insulating layer 110 more thermally conductive, which is desirable in certain embodiments, such as in a metal clad circuit board application. Having less binder in the circuit layer 112 makes the circuit layer 112 more conductive, which is desirable in certain applications. A binder having properties such as high paste quality, high printed film adhesion, film quality of the coating layers 106 after irradiation (e.g. low concentration of carbon residue (char) after irradiation), and the like are considered when selecting the binder material. In an exemplary embodiment, all or substantially all of the binder is irradiated by the electron beam 114 and a low amount of carbon residue remains, which may be removed by scraping or another processing technique.

During processing, the operation of the electron beam 114 may vary based on the type of material of the particular coating layer 106. For example, the operation may be different when using pure metallic material versus using metal precursors. The operation of the electron beam 114 may be different for the insulating layer 110 than for the circuit layer 112. In an exemplary embodiment, in the case of the pure metallic components, the post-processing and irradiation of the circuit layer 112 may be controlled by adjusting the energy density and exposure time in such a way that the metal particles sinter or at least one of the metallic components goes into the melt phase and the circuit layer 112 fuses into a homogeneous metallic layer. A two-step process with sintering and subsequent melting is possible in some embodiments. The non-metallic components (e.g. the binder) are segregated or vaporized leaving the pure metallic layer. In an exemplary embodiment, in the case of the metal precursors, such as metal oxides in, for example the insulating layer 110 (however such metal precursors may be used to form the circuit layer 112 in some embodiments), the post-processing and irradiation of the insulating layer 110 is controlled by the energy density and exposure time in such a way that the metal precursors are chemically reduced, either indirectly by the heat input into the insulating layer 110 or directly by interaction of the metal precursors with the electrons of the electron beam 114. The metal oxides may form electrically non-conductive but highly thermally conductive layers, which may be desired for the insulating layer 110 between the heat sink defined by the metal substrate 104 and the circuit layer 112. The non-metallic components (e.g. the binder) of the insulating layer 110 may be segregated or vaporized. The insulating layer 110 may transform into a homogeneous layer, such as an aluminum oxide layer, when the precursors are chemically altered by the electron beam 114.

The thermal energy generated by the electron beam 114 inside the coating layers 106 can be controlled by adjusting parameters of the electron beam 114. At low heat energies and long irradiation times, the coating layers 106 may be only partially melted and may not bond to the underlying structure. At low heat energies and long irradiation times the particles of the coating layers 106 may be only sintered and not completely melted. In such situations, the coating layers 106 may not adhere well to the underlying structures and may be easily displaced mechanically over time. At low heat energies but short irradiation times, portions of the coating layers 106 may be removed by the electron beam 114, such as by splattering away the material upon irradiation. At higher energies, large dewetted drops and three dimensional islands may remain, which is undesirable. At even higher energies, such as when the energy is too high, the underlying structures, such as the substrate 104 or the insulating layer 110, may melt in addition to the circuit layer 112, which provides a poorer electrical interface. The energy level of the electron beam 114 should be controlled to achieve melting of the coating layers 106 while having good covering of the underlying structure and without excessive damage to the underlying structure.

During use, particle blowing or spattering of the coating layers 106 may occur at any energy level. Several physical effects explain the effect of metal particle blowing: a) transfer of momentum, b) electrostatic effects, c) electrodynamic effects, and d) thermodynamic effects. To reduce particle blowing, the amount of non-metallic components may be reduced or minimized, since the less filler there is between the particles, the higher the number of conductive paths between the particles there are to ‘bleed off’ excessive charge to ground. To reduce particle blowing, the coating layers 106 or other layers of the substrate may be preheated such that lower beam power is required before the actual melting. For example, the coating layers 106 may be preheated to a temperature below the melting point of the coating layers 106, such as in a thermal oven, using the electron beam, or otherwise). During the irradiation process, the coating layers 106 are then further heated to a temperature above the melting point of the corresponding coating layer 106. To reduce particle blowing, larger particle sizes of the material of the coating layers 106 may be used or particles of irregular (non-spherical) shapes may be used to reduce effects of particle blowing, since more mechanical contacts between the particles could increase the forces to move particles relative to each other, as well as possibly creating more conductive paths. To reduce particle blowing, the scanning or irradiation pattern may be selected to heat the material of the coating layer 106 indirectly via heat conduction, such as through the substrate 104. To reduce particle blowing, the material composition of the coating layer 106 may have a high metal particle density and/or low porosity to increase the electrical and heat conductivity.

To avoid potential electrical charging of the substrate 104 during irradiation with the electron beam 114, the coating layers 106 may be grounded. To avoid potential electrical charging of the substrate 104 during irradiation with the electron beam 114, the electron beam 114 may be operated at low accelerating voltages to increase electron emission. To avoid potential electrical charging of the substrate 104 during irradiation with the electron beam 114, a light (e.g. UV or laser) may be used to increase the photoconductivity of the coating layers 106. To avoid potential electrical charging of the substrate 104 during irradiation with the electron beam 114, the coating layers 106 may be processed at an increased pressure (e.g. with argon partial pressure).

In an exemplary embodiment, the control of the electron beam 114, such as the amount of thermal energy generated by the electron beam 114, may be varied along the coating layers 106. For example, by changing operation of the electron beam 114 along one portion of the circuit layer 112 as compared to another portion of the circuit layer 112 the characteristics of the circuit layer 112 may be varied. For example, resistors may be incorporated into the electrical conductor paths or circuits by variation of the parameters of the electron beam 114. No assembly or mounting of resistors is then necessary. Additionally, the control of the electron beam 114 may be varied along the circuit layer 112 as compared to the insulating layer 110.

FIG. 4 illustrates another process for forming the electrical component 100 (shown in FIG. 1). In the illustrated embodiment, both the insulating layer 110 and the circuit layer 112 are deposited prior to processing with the electron beam 114. The electron beam 114 first processes the insulating layer 110. The circuit layer 112 is then later processed at a separate time. In such way, the electron beams may be controlled to specifically target one layer and then the other layer, such as with different operating parameters (e.g. different power level, different rate, and the like).

FIG. 5 illustrates another process for forming the electrical component 100 (shown in FIG. 1). In the illustrated embodiment, the insulating layer 110 is first deposited on the substrate 104 and then irradiated with the electron beam 114. The circuit layer 112 is then deposited on the processed insulating layer. The circuit layer 112 is then irradiated with the electron beam 114.

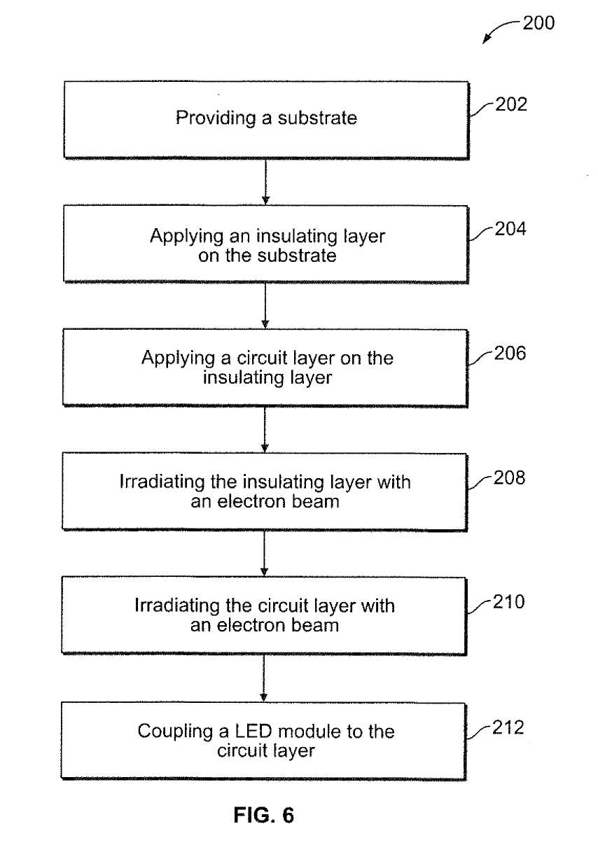

FIG. 6 illustrates a method 200 of manufacturing an electrical component, such as a metal clad circuit board. The method 200 includes providing 202 a substrate having an outer surface. In an exemplary embodiment, the substrate is a metal substrate, such as an aluminum substrate that functions as a heat sink for the electrical component.

The method 200 includes applying 204 an insulating layer on the outer surface of the substrate. The insulating layer may be a paste or ink. The insulating layer may be a powder or may have other forms. The insulating layer may include glass or ceramic forming materials that are transformed to glass or ceramic after being processed. The insulating layer may include precursors, such as metal oxides or metal salts that are processed at a later step. Optionally, the insulating layer may include binder to secure the insulating layer to the substrate. The binder concentration may be low, with the intention of removing substantially all of the binder during processing.

The insulating layer may be applied 204 by printing the insulating layer on the substrate. For example, the insulating layer may be screen printed, pad printed, ink jet printed, aerosol jet printed. The insulating layer may be applied by micro dispensing, spin coating, a wiping application, powder coating, spraying, dip immersion or other processes. The insulating layer may be applied directly to the outer surface of the substrate. Alternatively, other layers may be provided therebetween.

The method 200 includes applying 206 a circuit layer on the insulating layer. The circuit layer may be a paste or ink. The circuit layer may be a powder or may have other forms. The circuit layer may include a high concentration of metal particles. The circuit layer may include precursors, such as metal oxides or metal salts that are processed at a later step. Optionally, the circuit layer may include binder to secure the circuit layer to the insulating layer. The binder concentration may be low, with the intention of removing substantially all of the binder during processing.

The circuit layer may be applied 206 by printing the circuit layer on the insulating layer. For example, the circuit layer may be screen printed, pad printed, ink jet printed, aerosol jet printed. The circuit layer may be applied by micro dispensing, spin coating, a wiping application, powder coating, spraying, dip immersion or other processes. The circuit layer may be applied directly to the insulating layer. Alternatively, other layers may be provided therebetween.

Optionally, the insulating layer and the circuit layer, which define coating layers, may be preheated prior to other processing steps, such as processing the coating layers with an electron beam. The coating layers may be preheated to a temperature below a melting point of the coating layers prior to other processing steps, where the temperature may be increased to a temperature above the melting point of the coating layers.

Optionally, the coating layers may be electrically grounded prior to other processing steps, such as processing the coating layers with an electron beam. The grounding may reduce sputtering of the coating layers during processing with the electron beam.

The method 200 includes irradiating 208 the insulating layer with an electron beam to transform the insulating layer. The electron beam may be spot focused within the insulating layer. The irradiation with the electron beam may heat the insulating layer to melt the insulating layer to form an electrically non-conductive but thermally conductive layer between the metal substrate and the circuit layer. Optionally, the irradiation 208 may occur after the circuit layer is applied to the insulating layer. Alternatively, the irradiation 208 may occur prior to applying 206 the circuit layer to the insulating layer.

The irradiating 208 may vaporize substantially all the binder or non-metallic material of the insulating layer. The insulating layer may be irradiated until the non-metallic material of the insulating layer is completely removed. The irradiation process may be controlled, such as by controlling operating parameters of the electron beam, based on the properties of the insulating layer, such as the thickness, composition, concentration of binder, and the like. Optionally, different portions of the insulating layer may be irradiated differently.

The method 200 includes irradiating 210 the circuit layer with an electron beam to form an electrical conductor of the electrical component. The electron beam may be spot focused within the circuit layer. Optionally, the irradiation 210 may occur simultaneously with the irradiation 208 of the insulating layer, such as by controlling the irradiation source to emit electron beams into both coating layers. Both layers may be irradiated with the same electron beams. The irradiation with the electron beam may heat the circuit layer to melt the circuit layer to form the electrical conductor. Optionally, such as when metal precursors are used in the circuit layer, the metal precursors may interact with the electrons of the electron beam during irradiation to transform the circuit layer. The electron beam may chemically reduce the metal precursors to metals to form the electrical conductor.

The irradiating 210 may vaporize substantially all the binder or non-metallic material of the circuit layer leaving a substantially pure metallic layer to form the electrical conductor. The circuit layer may be irradiated until the non-metallic material of the circuit layer is completely removed. The irradiation process may be controlled, such as by controlling operating parameters of the electron beam, based on the properties of the circuit layer, such as the thickness, composition, concentration of binder, and the like. Optionally, different portions of the circuit layer may be irradiated differently, such as to form a resistor in the electrical conductor. The electrical component may be a structured electrical component. For example, layers of the electrical component may be printed in a structured way and irradiated via an electron beam to get predefined properties in one or more of the layers. The electrical component may be laminated or printed on or in a way to define a plane structure. Electron beams may irradiate all or selected portions of the layered structure, and then excess laminated/printed material may be removed.

The method includes coupling 212 a LED module to the circuit layer. The LED module may be soldered to the circuit layer. Heat from the LED module is dissipated by the substrate. The insulating layer is highly thermally conductive to allow efficient heat transfer therethrough to the substrate.

The methods and systems described herein of processing insulating and circuit layers 110, 112 with an electron beam 114 achieve a high quality layered structure on a metal substrate. The insulating layer 110 is electrically non-conductive and highly thermally conductive to dissipate heat from the circuit layer into the heat sink of the substrate 104. The process may be performed without wet chemistry and at reduced environmental impact. The metal consumption for manufacturing the electrical component may be reduced as compared to other manufacturing techniques. The process achieves high selectivity and precise placement of the coating layers 106. The coating layers 106 and electrical component may be processed quickly, and may be processed as part of a continuous reel-to-reel system or a discontinuous batch system. The electrical conductors defined by the processed circuit layer 112 provide improved properties compared to standard procedures. For example, the conductors may have increased electrical conductivity, increased thermal conductivity, better wear resistance, better corrosion resistance, increased hardness, and the like. The insulating layer defined by the processed insulating layer 110 provides improved properties compared to standard procedures. For example, the insulating layer may have a lower concentration of binder, which may increase the thermal conduction of the insulating layer.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc., are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

1. A method of manufacturing an electrical component, the method comprising:
providing a substrate;
applying an insulating layer on the substrate;
applying a circuit layer on the insulating layer;
irradiating the insulating layer with an electron beam to transform the insulating layer; and
irradiating the circuit layer with an electron beam to transform the circuit layer.

2. The method of claim 1, said irradiating the insulating layer and said irradiating the circuit layer occurs simultaneously.

3. The method of claim 1, said irradiating the insulating layer occurs prior to applying the circuit layer on the insulating layer.

4. The method of claim 1, wherein said irradiating the circuit layer comprises heating the circuit layer to melt the circuit layer to form an electrical conductor.

5. The method of claim 1, wherein said providing a substrate comprises providing a metallic substrate that is highly thermally conductive, said insulating layer providing electrical isolation between the circuit layer and the substrate.

6. The method of claim 1, further comprising preheating the circuit layer to a temperature below a melting point thereof prior to irradiating the circuit layers, said irradiating the circuit layer comprises heating the circuit layer to a temperature above the melting point of the circuit layer.

7. The method of claim 1, wherein said applying a an insulating layer comprises applying an insulating layer having a combination of binder and metal concentrations, said irradiating the insulating layer comprises vaporizing substantially all the binder leaving a substantially metallic layer to form the electrical conductor.

8. The method of claim 1, wherein applying an insulating layer comprises applying an insulating layer having glass or ceramic forming materials, said irradiating the insulating layer comprises irradiating the insulating layer to transform the glass or ceramic foil ling materials into glass or ceramic.

9. The method of claim 1, wherein said applying an insulating layer comprises printing the insulating layer directly on the outer surface of the substrate, wherein said applying a circuit layer comprises printing the circuit layer directly on the insulating layer,

10. The method of claim 1, further comprising coupling a light emitting diode module to the circuit layer.

11. The method of claim 1, further comprising electrically grounding the circuit layer during the irradiating process.

12. An electrical component comprising:
a substrate having an outer surface;
an insulating layer selectively applied to the outer surface, the insulating layer being configured in a pre-processing state and in a post-processing state after irradiating with an electron beam, the insulating layer being transformed from the pre-processing state to the post-processing state, wherein an electron beam at least partially penetrates the insulating layer during the irradiating to transform the insulating layer; and
a circuit layer selectively applied to the insulating layer, the circuit layer being configured in a pre-processing state and in a post-processing state after irradiating with an electron beam, the circuit layer being transformed from the pre-processing state to the post-processing state, wherein an electron beam at least partially penetrates the circuit layer during the irradiating to transform the circuit layer.

13. The electrical component of claim 12, wherein the electron beam irradiates the insulating layer and the circuit layer simultaneously.

14. The electrical component of claim 12, wherein the irradiation of the insulating layer occurs prior to applying the circuit layer to the insulating layer.

15. The electrical component of claim 12, wherein the substrate is manufactured from a metallic material, the insulating layer providing electrical isolation of the circuit layer from the substrate.

16. The electrical component of claim 12, wherein a non-metallic material content of the circuit layer is higher at the pre-processing state than the post-processing state, the non-metallic material being removed during irradiating by the electron beam.

17. An electrical component forming system comprising:
a chamber;
an irradiation source generating electron beams; and
a substrate positioned in the chamber, the substrate having an insulating layer selectively applied to the substrate, corresponding electron beams at least partially penetrating the insulating layer to transform the insulating layer, the substrate having a circuit layer selectively applied to the insulating layer, corresponding electron beams at least partially penetrating the circuit layer to transform the circuit layer.

18. The system of claim 17, wherein the insulating layer is configured in a pre-processing state and in a post-processing state after irradiating with the electron beam, the insulating layer being transformed from the pre-processing state to the post-processing state, wherein an electron beam at least partially penetrates the insulating layer during the irradiating process to transform the insulating layer, and wherein the circuit layer is configured in a pre-processing state and in a post-processing state after irradiating with the electron beam, the circuit layer being transformed from the pre-processing state to the post-processing state, wherein an electron beam at least partially penetrates the circuit layer during the irradiating process to transform the circuit layer.

19. The system of claim 17, wherein the irradiation of the insulating layer occurs prior to applying the circuit layer to the insulating layer.

20. The system of claim 17, wherein the circuit layer has a low binder concentration when applied to the insulating layer, substantially all of the binder being removed during the irradiating process by the electron beam.
